(19) United States
(12) Patent Application Publication
(10) Pub. No.: US 2015/0221475 A1
(43) Pub. Date: Aug. 6, 2015

(54) PLASMA PROCESSING DEVICE AND PLASMA PROCESSING METHOD

(71) Applicant: Panasonic Intellectual Property Management Co., Ltd., Osaka (JP)

(72) Inventor: TOMOHIRO OKUMURA, Osaka (JP)

(21) Appl. No.: 14/606,925

(22) Filed: Jan. 27, 2015

(30) Foreign Application Priority Data
Feb. 4, 2014 (JP) 2014-019051

(51) Int. Cl. H01J 37/32; H01L 21/3065; H01L 21/02; C23C 16/513

(52) U.S. Cl. CPC H01J 37/321; H01J 37/32715; H01J 37/3244; C23C 16/513; H01L 21/3065; H01L 21/02274; H01J 2237/334; H01J 2237/332

(57) ABSTRACT

In A plasma processing device and method is capable of efficiently generating long thermal plasma with good uniformity as well as suppressing electrostatic discharge damage, a substrate on which a thin film is formed is arranged so as to face an inductively-coupled plasma torch unit. Coils are arranged in the vicinity of a first ceramic block and a second ceramic block of the torch unit. A shielding plate in the torch unit effectively shields high-frequency electromagnetic fields generated by the coils to drastically reduce the high-frequency electromagnetic fields in the vicinity of the substrate. Therefore, electrostatic discharge damage hardly occurs.

### TECHNICAL FIELD

The technical field relates to a plasma processing device and a plasma processing method such as thermal plasma processing which processes a substrate by irradiating the substrate with thermal plasma by using an inductively-coupled plasma torch and plasma processing which processes the substrate by irradiating the substrate with plasma by a reactant gas or with plasma and a reactant gas flow at the same time.

### BACKGROUND

A semiconductor thin film such as polycrystalline silicon (poly-Si) is widely used for a thin-film transistor (TFT) and a solar cell in related art. A method of forming the semiconductor thin film is irradiating an amorphous silicon film with laser light to crystallize the film. The laser process can be also applied to activation of impurity atoms introduced into a semiconductor substrate by ion implantation or plasma doping. However, the laser annealing technique has problems such as occurrence of a seam, and further, extremely expensive equipment is necessary.

Accordingly, a technique of performing heat treatment inexpensively without occurrence of a seam by generating long thermal plasma and performing scanning only in one direction has been studied (for example, refer to JP-A-2013-120633 (Patent Document 1), JP-A-2013-120684 (Patent Document 2), JP-A-2013-120685 (Patent Document 3), JP-A-2011-071010 (Patent Document 4) and Non-Patent Document 1.)

A common problem in plasma processing is so-called electrostatic discharge damage. This is a problem in which a balanced state of electronic current and ion current flowing into a processed object (substrate) is locally lost and electric charges are accumulated due to spatial nonuniformity of plasma. As a result, when the substrate includes a transistor, there arise problems such that a gage insulating film is deteriorated by tunneling current, and thus, a withstand voltage is lowered or a flat band voltage varies (for example, refer to Non-Patent Document 2).

There is a method called a remote method which can suppress the electrostatic discharge damage in capacitively-coupled low-temperature atmospheric plasma used for surface washing and so on. When comparing a direct method in which the substrate is arranged inside a plasma space and the remote method in which the substrate is arranged outside the plasma space, the electrostatic discharge damage is assumed to be reduced in the remote method )for example, refer to JP-A-2003-100646 (Patent Document 5)).

### NON-PATENT DOCUMENTS

[Non-Patent Document 1] T. Okumura and H. kawaura, Jpn. J. Appl. Phys. 52 (2013) (2002) 83.

[Non-Patent Document 2] Yoshito Fukumoto, Shingo Sumie, “Development of Plasma Charge-up Damage Evaluation Wafers”, Kobe Steel Engineering reports, 52 (2002) 83

### SUMMARY

However, in the method of using an annular chamber described in Patent Documents 1 to 3 and Non-Patent Document 1 by the present inventors, there is a problem in which electrostatic discharge damage occurs in the substrate by high-frequency electromagnetic fields generated by coils. In a direct-current torch described in Patent Document 4, it is difficult to efficiently generate the long thermal plasma with good uniformity. In the capacitively-coupled low-temperature atmospheric plasma described in Patent Document 5, the temperature of plasma is low (lower than 1000° C.), which is not suitable for heat treatment and high-speed processing.

In view of the above problems, as well as other concerns, the present disclosure concerns a plasma processing device and a plasma processing method capable of efficiently generating long thermal plasma with good uniformity as well as suppressing electrostatic discharge damage.

According to an embodiment, a plasma processing device includes an inductively-coupled plasma torch having a chamber surrounded by a dielectric member, an opening communicated to the chamber, a gas supply pipe introducing a gas to the inside of the chamber and a coil provided in the vicinity of the chamber, a high-frequency power supply connected to the coil, a substrate mounting table facing the opening and holding the substrate, and a conductive member provided at portions except the opening between the coil and the substrate mounting table.

According to the above structure, electrostatic discharge damage can be suppressed.

In the plasma processing device according to the embodiment, it is preferable that the chamber is an annular long chamber communicated to the slit-shaped opening, a longitudinal direction of the chamber is arranged in parallel to a longitudinal direction of the opening, and a moving mechanism which can relatively move the chamber and the substrate in a direction perpendicular to the longitudinal direction of the opening is included.

According to the above structure, it is possible to efficiently generate long thermal plasma with good uniformity as well as to suppress electrostatic discharge damage.

It is preferable that the chamber is arranged perpendicular to a flat surface formed by the substrate mounting table.

According to the above structure, the plasma processing device with a simpler structure can be realized.

It is preferable that the chamber is integrated with the conductive member.

According to the above structure, processing at higher speed can be realized.

It is preferable that the conductive member is made of any of silicon, silicon carbide and carbon.

According to the above structure, processing with little contamination due to unnecessary impurities can be realized.

The conductive member can be made of plural linear members parallel to the longitudinal direction of the chamber. The conductive member can also be made of a netlike member.

According to the above structure, the inductively-coupled plasma torch can be reduced in weight.

A plasma processing method using an inductively-coupled plasma torch according to an embodiment includes the steps of ejecting a gas from an opening communicating to a chamber toward a substrate while supplying the gas into the chamber surrounded by a dielectric, and generating high-frequency electromagnetic fields in the chamber and generating plasma by supplying high-frequency power to a coil in a state where the coil is arranged in the vicinity of the chamber to thereby process the surface of the substrate, in which the substrate is processed in a state where a conductive member is provided at portions except the opening between the coil and the substrate mounting table.

According to the above structure, electrostatic discharge damage can be suppressed.

According to the embodiment, it is possible to provide the plasma processing device and the plasma processing method capable of efficiently generating long thermal plasma with good uniformity as well as suppressing electrostatic discharge damage.

### BRIEF DESCRIPTION OF THE DRAWINGS

FIGS. 1A and 1B are cross-sectional views showing a structure of a plasma processing device according to Embodiment 1;

FIG. 2 is a perspective view showing the structure of the plasma processing device according to Embodiment 1;

FIG. 3 is a cross-sectional view showing a structure of a plasma processing device according to Embodiment 2;

FIG. 4 is a cross-sectional view showing a structure of a plasma processing device according to Embodiment 3;

FIG. 5 is a cross-sectional view showing a structure of a plasma processing device according to Embodiment 4;

FIG. 6 is a cross-sectional view showing a structure of a plasma processing device according to Embodiment 5;

FIG. 7 is a cross-sectional view showing a structure of a plasma processing device according to Embodiment 6;

FIG. 8 is a cross-sectional view showing a structure of a plasma processing device according to Embodiment 7;

FIG. 9 is a cross-sectional view showing a structure of a plasma processing device according to Embodiment 8; and

FIG. 10 is a cross-sectional view showing a structure of a plasma processing device according to Embodiment 9.

### DESCRIPTION OF THE PREFERRED EMBODIMENTS

Hereinafter, a plasma processing device according to various exemplary embodiments will be explained with reference to the drawings.

### Embodiment 1

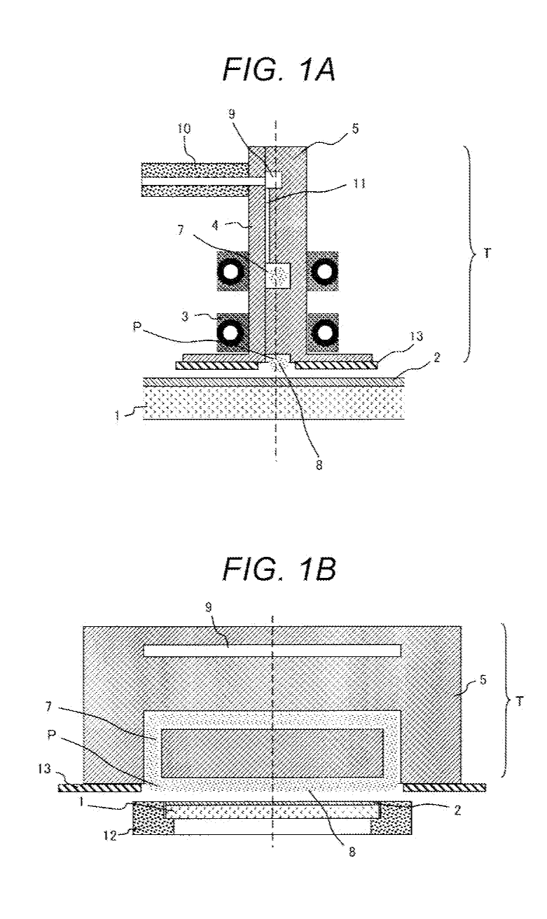

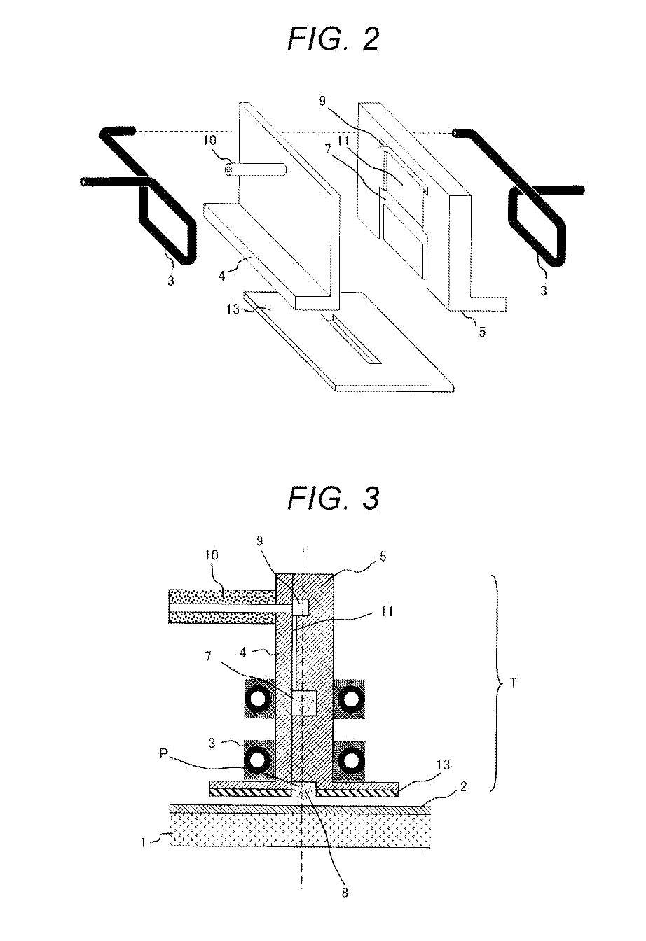

Embodiment 1 will be explained with reference to FIGS. 1A, 1B and FIG. 2 below.

FIG. 1A shows a structure of a plasma processing device according to Embodiment 1, which is a cross-sectional view taken along a surface perpendicular to a longitudinal direction of an inductively-coupled plasma torch unit T. FIG. 1B is a cross-sectional view taken along a surface parallel to the longitudinal direction of the inductively-coupled plasma torch unit as well as perpendicular to a substrate. FIG. 1A is a cross-sectional view taken along a broken line of FIG. 1B, FIG. 1B is a cross-sectional view taken along a broken line of FIG. 1A and FIG. 2 is an assembly structure view of the inductively-coupled plasma torch unit shown in FIG. 1A and FIG. 1B, in which perspective views of respective parts (portions) are aligned.

In FIGS. 1A, 1B and 2, a thin film 2 is formed on a substrate 1. In an inductively-coupled plasma torch unit T, coils 3 made of conductors are disposed in the vicinity of a first ceramic block 4 and a second ceramic block 5 which are made of a dielectric. Each coil 3 is formed by adhering a copper pipe having a circular shape in cross section to a copper block having a rectangular parallelepiped shape in cross section. A long chamber 7 made of the dielectric is defined by a space surrounded by the first ceramic block 4, the second ceramic block 5 and the thin film 2 forming the surface of the substrate 1. The long chamber 7 is provided along a surface perpendicular to a surface formed by the substrate 1. The coil 3 is arranged so that the central axis thereof is parallel to the substrate 1 as well as perpendicular to a flat surface including the long chamber 7. That is, a surface formed by a winding of the coil 3 is arranged along the surface perpendicular to the surface formed by the substrate 1 as well as along the fiat surface including the long chamber 7.

The inductively-coupled plasma torch unit T is surrounded by a shielding member (not shown) made of a conductor which is entirely grounded, therefore, leakage (noise) of high-frequency waves can be effectively prevented as well as undesirable abnormal discharge can be effectively prevented.

The long chamber 7 is surrounded by one fiat surface of the first ceramic block 4 and a groove provided in the second ceramic block 5. The two dielectric blocks as dielectric members are bonded to each other. That is, the long chamber 7 is surrounded by the dielectric except an opening 8. The long chamber 7 has an annular shape. The annular shape means, in this case, a closed continuous string shape, and is not limited to a circular shape.

In the embodiment, the chamber 7 having a rectangular shape (closed continuous string shape formed by straight-line portions forming two long sides and straight lines forming two short sides connected to both ends of long sides) is shown as an example. Plasma P generated in the long chamber 7 contacts the thin film 2 forming the surface of the substrate 1 in the opening 8 having a long linear shape in the chamber 7. The longitudinal direction of the long chamber 7 is arranged in parallel to the longitudinal direction of the opening 8.

A plasma gas manifold 9 is provided inside the second ceramic block 5. The gas supplied from a plasma gas supply pipe 10 to the plasma gas manifold 9 is introduced to the long chamber 7 through a plasma gas supply hole 11 (through hole) as a gas introducing portion provided in the second ceramic block 5.

According to the structure, the gas flow which is uniform in the longitudinal direction can be easily realized. A flow amount of the gas to be introduced to the plasma gas supply pipe 10 is controlled by providing a flow controller such as a mass-flow controller upstream.

The plasma supply hole 11 is a long slit or may be constructed by forming plural round holes in the longitudinal direction.

The substrate 1 is mounted on a substrate holder 12 as a substrate mounting table. In the substrate holder 12, a through hole having a shape approximately similar to and slightly smaller than an outer shape of the substrate 1 and a counterbore portion having a shape approximately similar to and slightly larger than the outer shape of the substrate 1. A depth of the counterbore portion is formed to be approximately equal to a thickness of the substrate 1 so that portions in a surface of the substrate holder 12 facing the inductively-coupled plasma torch unit T, which are the outside of the counterbore portion, and the surface of the substrate 1 make approximately the same plane by placing the substrate 1 on the counterbore portion.

According to the above structure, when the substrate holder 12 moves relatively with respect to the inductively-coupled plasma torch unit T, the shape of the annular long chamber 7 as the space where plasma is generated is approximately fixed regardless of the position of the substrate holder 12. That is, it is possible to suppress fluctuation of plasma occurring with the movement.

The inside of the copper pipe in each coil 3 is a refrigerant flow path. The copper block adhered to the outside thereof is adhered to the first ceramic block 4 or the second ceramic block 5 by an adhesive (not shown). As the cross section of the coil 3 is a rectangular parallelepiped shape as described above, the adhesive with respect to the first ceramic block 4 or the second ceramic block 5 can be as thin as possible, therefore, good thermal conductivity can be secured. Accordingly, the coils 3, the first ceramic block 4 and the second ceramic block 5 can be cooled by allowing a refrigerant such as water to flow in copper pipes forming the coils 3.

The coils 3 are respectively arranged outside the first ceramic block 4 and outside the second ceramic block 5 as well as connected in series at positions apart from the long chamber 7 so that directions of high-frequency electromagnetic fields generated in the long chamber 7 are the same when high-frequency power is applied. The device can function only by one of these two coils 3, however, there is an advantage that the intensity of the electromagnetic fields generated in the long chamber 7 can be increased when providing two coils in a state of interposing the long chamber 7 therebetween as in the embodiment.

In the lowest part of the inductively-coupled plasma torch unit T, a shielding plate 13 as a conductive member is provided at portions except the opening 8 between the coils 3 and the substrate holder 12. The structure is the same as that of related art in a point that an inner peripheral portion of the annular long chamber 7 is formed by an insulator member over the whole periphery. The shielding plate 13 is made of silicon into which a very slight amount of impurity is introduced. The shielding plate 13 is integrated with the long chamber 7.

Here, “the shielding plate 13 is integrated with the long chamber 7” means that the first ceramic block 4 and the second ceramic block 5 forming the long chamber 7 are integrated with the shielding plate 13 without any gap.

According to the above structure, the distance between the inductively-coupled plasma torch unit T and the substrate 1 is not greatly different from the related art; therefore, high speed processing similar to the related art can be realized. Additionally, the device is configured so that a through hole provided in the central portion of the shielding plate 13 is larger than a concave portion in the vicinity of the opening 8 of the second ceramic block 5. In this structure, it is possible to reduce physical/thermal damage given to the shielding plate 13 by high-temperature plasma.

Although the case where the shielding plate 13 is made of silicon has been cited as an example, the shielding plate 13 can be made of any of silicon carbide and carbon. These materials have an advantage that contamination to the substrate 1 (or the thin film 2 on the substrate 1) is relatively small. That is, processing with small contamination due to unnecessary impurities can be realized by selecting the above materials.

The rectangular linear opening 8 is provided, and the substrate 1 (or the thin film 2 on the substrate 1) is arranged opposite to the opening 8. A high frequency power of, for example, 13.56 MHz is supplied to the coils 3 from a not-shown high-frequency power supply while supplying the gas into the long chamber 7 and ejecting the gas from the opening 8 in advance, thereby generating the plasma P in the long chamber 7. Then, the substrate 1 is moved to the vicinity of the inductively-coupled plasma torch unit T and the thin film 2 forming the surface of the substrate 1 is exposed to plasma near the opening 8, thereby performing plasma processing to the thin film 2 on the substrate 1.

The substrate 1 is processed by moving the long chamber 7 and the substrate 1 relatively in a direction perpendicular to the longitudinal direction of the opening 8. That is, the inductively-coupled plasma torch unit T or the substrate 1 is moved in a right and left direction of FIG. 1A as well as in a direction perpendicular to the page in FIG. 1B.

Various kinds of gases can be used as the gas to be supplied to the long chamber 7, but it is desirable to mainly use inert gases, when considering stability and ignition performance of plasma, lifetime of members exposed to plasma and so on. Among them, an Ar gas is typically used. When plasma is generated only by the Ar gas, plasma will be a considerably high temperature (10,000K or more).

As conditions for generating plasma, appropriate values are approximately: scanning speed=50 to 3000 mm/s, the total flow rate of plasma gas=1 to 100 SLM, H₂ density in Ar+H₂ gas=0 to 10%, and high frequency power=0.5 to 50 kW. The gas flow rate and the power in these values show values per a length 100 mm of the opening 8. It is because, it is suitable that an amount proportional to the length of the opening 8 is inputted concerning parameters such as the gas flow rate and the power.

As described above, the long chamber and the substrate 1 are relatively moved in the direction perpendicular to the longitudinal direction of the opening 8 while the longitudinal direction of the opening 8 is arranged in parallel to the substrate 1, therefore, it is possible to construct the device so that the length of plasma to be generated is substantially equivalent to the length of the substrate 1 to be processed as shown in FIG. 1B.

As the surface of the substrate 1 is exposed to a portion having high temperature, high electron density and high active particle density in the plasma P, high-speed processing or high-temperature processing can be realized.

As the high-frequency electromagnetic fields generated by the coils 3 are effectively shielded by the shielding plate 13 in the above structure, the high-frequency electromagnetic fields in the vicinity of the substrate 1 are drastically reduced, therefore, electrostatic discharge damage hardly occurs. This has been confirmed by the fact that a MOS device with an antenna ratio: 1,000,000 times is not broken according to the antenna MOS evaluation similar to the description of Non-Patent Document 2 and the fact that little electric charges are generated in an insulating thin film on the substrate 1 (±3V or less) by the Kelvin probe method.

As a result of evaluation of the electrostatic discharge damage in a state where there is no shielding plate 13 for purpose of comparison, it has been found that the MOS device with the antenna ratio: 1,000,000 times is broken, and further, the MOS device with antenna ratio: 10,000 times is also broken. Furthermore, it has been found that electric charges at +10 to 30V are generated in the insulating thin film on the substrate 1 in the evaluation by the Kelvin probe method.

According to the above, it has been found that the electrostatic discharge damage is effectively suppressed in the present embodiment, though conspicuous electrostatic discharge damage is generated in the related art structure.

### Embodiment 2

Hereinafter, Embodiment 2 will be explained with reference to FIG. 3.

FIG. 3 is a cross-sectional view taken along a surface perpendicular to a longitudinal direction of an inductively-coupled plasma torch unit T according to Embodiment 2, which corresponds to FIG. 1A.

In FIG. 3, the device is configured so that a concave portion in the vicinity of the opening 8 of the second ceramic block 5 has approximately the same size as a through hole provided in the central portion of the shielding plate 13. In the structure, there is little danger that plasma fluctuates in a right and left direction of FIG. 3.

### Embodiment 3

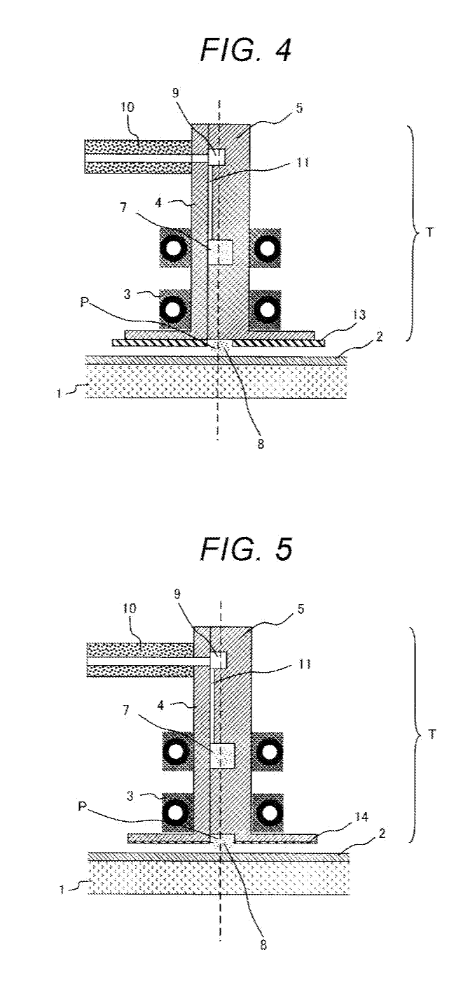

Hereinafter, Embodiment 3 will be explained with reference to FIG. 4.

FIG. 4 is a cross-sectional view taken along a surface perpendicular to a longitudinal direction of an inductively-coupled plasma torch unit T according to Embodiment 3, which corresponds to FIG. 1A.

In FIG. 4, the concave portion is not provided in the vicinity of the opening 8 of the second ceramic block 5, and the concave portion in the vicinity of opening 8 is formed by a through hole provided in the central portion of the shielding plate 13. As high-temperature plasma is allowed to be close to the substrate 1 in this structure, efficient processing can be realized.

### Embodiment 4

Hereinafter, Embodiment 4 will be explained with reference to FIG. 5.

FIG. 5 is a cross-sectional view taken along a surface perpendicular to a longitudinal direction of an inductively-coupled plasma torch unit T according to Embodiment 4, which corresponds to FIG. 1A.

In FIG. 5, a metal thin film 14 as a conductive member is provided instead of the shielding plate 13. As the distance between the coils 3 and the substrate 1 can be shortened in this structure, plasma can be effectively generated.

### Embodiment 5

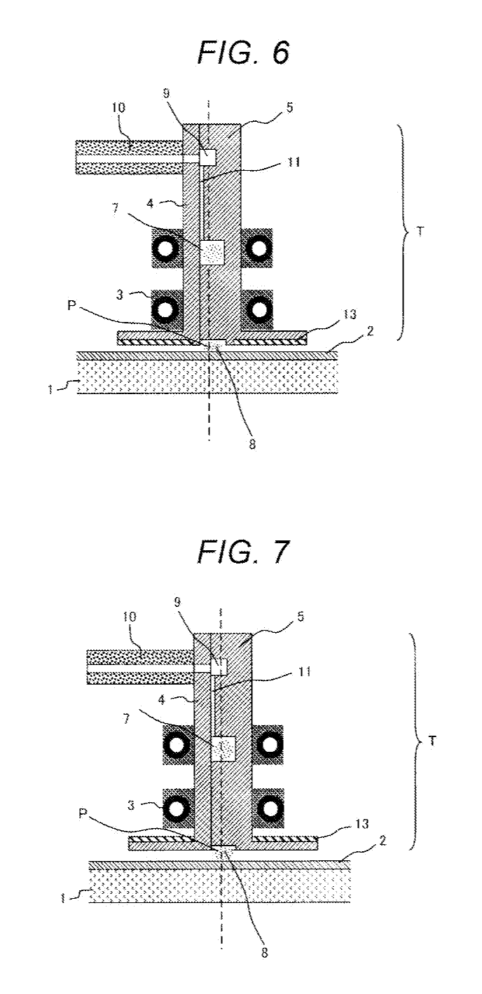

Hereinafter, Embodiment 5 will be explained with reference to FIG. 6.

FIG. 6 is a cross-sectional view taken along a surface perpendicular to a longitudinal direction of an inductively-coupled plasma torch unit T according to Embodiment 5, which corresponds to FIG. 1A.

In FIG. 6, part of portions of the first ceramic block 4 and the second ceramic block 5 which faces the substrate 1 is formed to be a convex portion, the concave portion in the vicinity of the opening 8 is surrounded by the dielectric member in the same manner as related art as well as the outside of the vicinity of the opening 8 is covered with the shielding 13 as the conductive member. As high-temperature plasma directly contacts only the first ceramic block 4 and the second ceramic block 5 in this structure, effects with respect to the inductively-coupled plasma torch unit T due to thermal damage can be reduced.

### Embodiment 6

Hereinafter, Embodiment 6 will be explained with reference to FIG. 7.

FIG. 7 is a cross-sectional view taken along a surface perpendicular to a longitudinal direction of an inductively-coupled plasma torch unit T according to Embodiment 6, which corresponds to FIG. 1A.

In FIG. 7, the shielding plate 13 is arranged on surfaces opposite to the substrate 1, which are eaves portions (portions positioned between the coils 3 and the substrate 1) of the first ceramic block 4 and the second ceramic block 5. Although the cooling performance at portions close to the substrate 1 in the inductively-coupled plasma torch unit T is reduced as it is necessary to provide a space for insulation between the coils 3 and the shielding plate 13 in this structure, a possibility that the shielding plate 13 receives damage due to the high-temperature plasma can be almost eliminated. Additionally, the contamination to the substrate 1 due to impurities generated from the shielding plate 13 can be almost ignored in this structure, therefore, the shielding plate 13 can be formed by using metal materials such as aluminum and copper.

### Embodiment 7

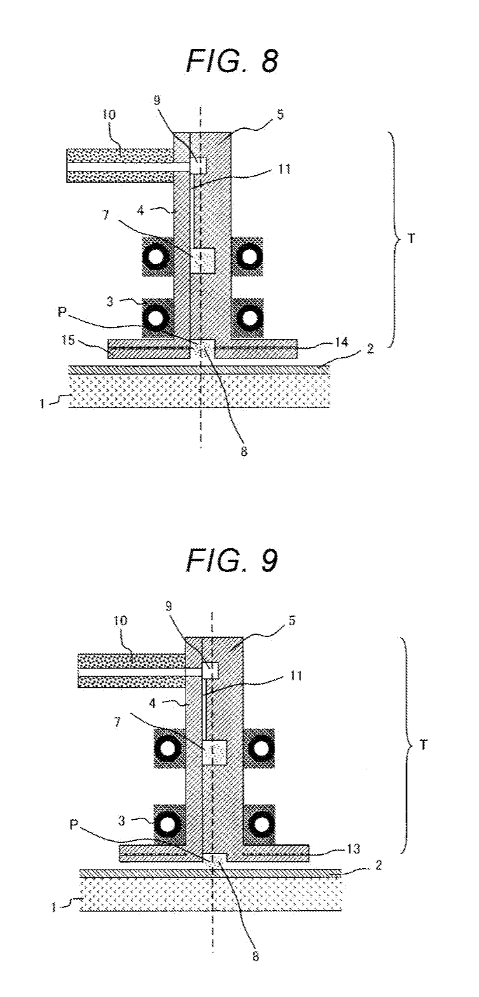

Hereinafter, Embodiment 7 will be explained with reference to FIG. 8.

FIG. 8 is a cross-sectional view taken along a surface perpendicular to a longitudinal direction of an inductively-coupled plasma torch unit T according to Embodiment 7, which corresponds to FIG. 1A.

In FIG. 8, the metal thin film 14 as the conductive member is provided instead of the shielding plate 13 in the same manner as Embodiment 4, and further, an insulating plate 15 is provided between the shielding plate 13 and the substrate 1. In this structure, the possibility that the shielding plate 13 receives damage by high-temperature plasma can be reduced.

### Embodiment 8

Hereinafter, Embodiment 8 will be explained with reference to FIG. 9.

FIG. 9 is a cross-sectional view taken along a surface perpendicular to a longitudinal direction of an inductively-coupled plasma torch unit T according to Embodiment 8, which corresponds to FIG. 1A.

In FIG. 9, an extremely thin shielding plate 13 is inserted into slits parallel to the substrate 1, which are provided in the eaves portions of the first ceramic block 4 and the second ceramic block 5. As high-temperature plasma directly contacts only the first ceramic block 4 and the second ceramic block 5 in this structure, effects with respect to the inductively-coupled plasma torch unit T due to thermal damage can be reduced.

Additionally, the contamination to the substrate 1 due to impurities generated from the shielding plate 13 can be almost ignored in this structure, therefore, the shielding plate 13 can be formed by using metal materials such as aluminum and copper.

### Embodiment 9

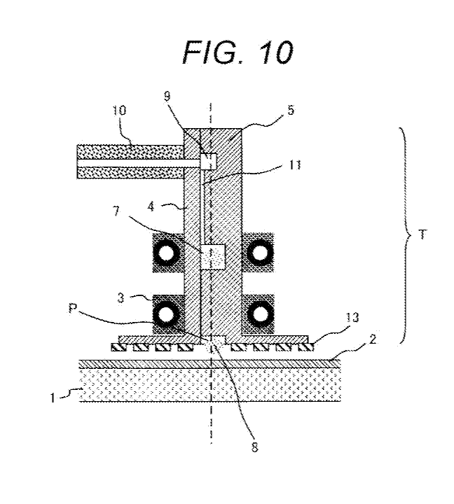

Hereinafter, Embodiment 9 will be explained with reference to FIG. 10.

FIG. 10 is a cross-sectional view taken along a surface perpendicular to a longitudinal direction of an inductively-coupled plasma torch unit T according to Embodiment 9, which corresponds to FIG. 1A.

In FIG. 10, the shielding plate 13 is made of plural linear members parallel to the longitudinal direction of the long chamber 7. As the coils 3 have a long shape, directions of the high-frequency electric fields generated in the vicinity of the coils 3 are parallel to the longitudinal direction of the long chamber 7. Accordingly, the high-frequency electromagnetic fields can be effectively shielded also by the plural linear members parallel to the longitudinal direction of the long chamber 7. According to the structure, the inductively-coupled plasma torch can be reduced in weight. The conductive member can be made of a netlike member.

The above-described plasma processing devices and methods are just typical examples in the application range of the embodiments.

Though the case where the substrate holder 12 is scanned with respect to the fixed inductively-coupled plasma torch unit T has been cited as the example, however, it is preferable that, for example, the inductively-coupled plasma torch unit T is scanned with respect to the fixed substrate mounting table.

It is also possible to perform high-temperature treatment to the vicinity of the surface of the substrate 1 by various structures in accordance with the various embodiments. That is, the above embodiments can be applied to crystallization of the semiconductor film for a TFT and improvement of the semiconductor film for a solar cell which has been described in detail in related art. The above embodiments can be also applied to various surface processing such as clean-up and the reduction of degassing of a protective layer of a plasma display panel, the surface planarization and the reduction of degassing of a dielectric layer made of an aggregation of silica particles, RTP (Rapid Thermal Processing) of semiconductor devices, the reflow of various electronic devices, and plasma doping using a solid impurity source.

The word “thermal plasma” is used in the explanation for simplification, however, it is strictly difficult to distinguish between thermal plasma and low-temperature plasma. It is also difficult to distinguish types of plasma only based on the thermal equilibria, for example, as commented in “Non-equilibria of thermal plasma” by Tanaka Yasunori in a journal of plasma and fusion research vol. 82, No. 8 (2006) pp. 479-483.

A concern of the present disclosure is to perform heat treatment to the substrate, and the various exemplary embodiments can be applied to the technique of irradiating high-temperature plasma regardless of words such as thermal plasma, thermal equilibria plasma and high-temperature plasma.

Though the case where high-temperature heat treatment is performed uniformly to the vicinity of the surface of the substrate for a very short period of time has been explained in detail as an example, in another exemplary embodiment, plasma processing is performed to the substrate by irradiating the substrate with plasma by a reactant gas or with plasma and the reactant gas flow at the same time. When the reactant gas is mixed with the plasma gas, etching or CVD can be realized by irradiating the substrate with plasma by the reactant gas.

Alternatively, a gas including a reactant gas as a shielding gas is supplied to the vicinity of the plasma gas while using a noble gas or a gas obtained by adding a small amount of H₂ gas to the noble gas as a plasma gas, thereby irradiating the substrate with plasma and the reactant gas flow at the same time and realizing plasma processing such as etching, CVD and doping.

When using the gas mainly containing argon as the plasma gas, thermal plasma is generated as explained in the embodiments in detail. On the other hand, when using a gas mainly containing helium as a plasma gas, relatively low-temperature plasma can be generated. It is possible to perform processing such as etching and deposition without heating the substrate too much by using the above method. As reactant gases used for etching, there are halogen-containing gases such as CxFy (x and y are natural numbers) and SF₆, whereby performing etching of silicon, silicon compounds and the like. When O₂ is used as the reactant gas, removal of organic matters, resist ashing, formation of an extremely-thin oxide film and so on can be performed.

As reactant gases used for CVD, there are monosilane, disilane and so on, whereby performing deposition of silicon and silicon compounds. Alternatively, when using a mixed gas of an organic gas containing silicon represented by TEOS (Tetraethoxysilane) and O₂, a silicon oxide film can be deposited.

Other various plasma processing such as surface processing for improving water repellency and hydrophilia can be performed. As the structure of the various exemplary embodiments relates to the inductively-coupled type device, the arc discharge does not easily occur even when higher power density per a unit volume is inputted, therefore, higher density plasma can be generated. As a result, higher reaction speed can be obtained and the entire desired treated region of the substrate can be processed efficiently for a short period of time.

As described above, the plasma processing device according to the various exemplary embodiments can be applied to crystallization of the semiconductor film for a TFT and improvement of the semiconductor film for a solar cell. Naturally, the plasma processing device is useful in various surface processing such as clean-up and the reduction of degassing in a protective layer of a plasma display panel, the surface planarization and the reduction of degassing in a dielectric layer made of an aggregation of silica particles, RTP of semiconductor devices, the reflow of various electronic devices, and plasma doping using a solid impurity source.

The plasma processing device is also useful for processing the entire desired treated region of the substrate for a short period of time efficiently in plasma processing such as etching, deposition, doping and surface improvement in the manufacture of various electronic devices.

What is claimed is:

1. A plasma processing device comprising:
an inductively-coupled plasma torch including a chamber surrounded by a dielectric member, an opening communicated to the chamber, a gas supply pipe introducing a gas to the inside of the chamber, and a coil provided in the vicinity of the chamber;
a high-frequency power supply connected to the coil; and
a substrate mounting table facing the opening and holding the substrate,
wherein a conductive member is provided at portions except the opening between the coil and the substrate mounting table.

2. The plasma processing device according to claim 1,
wherein the chamber is an annular long chamber communicated to the slit-shaped opening,
a longitudinal direction of the chamber is arranged in parallel to a longitudinal direction of the opening, and
a moving mechanism which can relatively move the chamber and the substrate in a direction perpendicular to the longitudinal direction of the opening is included.

3. The plasma processing device according to claim 1,
wherein the chamber is arranged perpendicular to a flat surface formed by the substrate mounting table.

4. The plasma processing device according to claim 1,
wherein the chamber is integrated with the conductive member.

5. The plasma processing device according to claim 1,
wherein the conductive member is made of any of silicon, silicon carbide and carbon.

6. The plasma processing device according to claim 1,
wherein the conductive member is made of plural linear members parallel to the longitudinal direction of the chamber.

7. The plasma processing device according to claim 1,
wherein the conductive member is made of a netlike member.

8. A plasma processing method using an inductively-coupled plasma torch, comprising the steps of:
ejecting a gas irons an opening communicating to a chamber toward a substrate while supplying the gas into the chamber surrounded by a dielectric, and
generating high-frequency electromagnetic fields in the chamber and generating plasma by supplying high-frequency power to a coil in a state where the coil is arranged in the vicinity of the chamber to thereby process the surface of the substrate,
wherein the substrate is processed in a state where a conductive member is provided at portions except the opening between the coil and the substrate mounting table.

9. The plasma processing device according to claim 1,
wherein the conductive member includes an opening portion having a size larger than a size of the opening, is provided on a bottom portion of the dielectric member and faces the substrate mounting table.

10. The plasma processing device according to claim 1,
wherein the conductive member includes an opening portion having a size approximately same as a size of the opening, is provided on a bottom portion of the dielectric member and faces the substrate mounting table.

11. The plasma processing device according to claim 1,
wherein the dielectric member includes a convex portion surrounding the opening,
wherein the conductive member is provided on the bottom portion of the dielectric member, extends to the convex portion and faces the substrate mounting table.

12. The plasma processing device according to claim 1,
wherein the conductive member is provided on a top surface of a bottom portion of the dielectric member.

13. The plasma processing device according to claim 1, further comprising an insulating plate provided between the conductive member and the substrate.

14. The plasma processing device according to claim 1, wherein the conductive member is provided in slits in the dielectric member which are parallel to the substrate.
